(19) United States
(12) Patent Application Publication
(10) Pub. No.: US 2025/0151242 A1
(43) Pub. Date: May 8, 2025

(54) DEVICE WITH EXCHANGEABLE ELECTRONICS ASSEMBLIES OF A MOTOR VEHICLE

(71) Applicant: Robert Bosch GmbH, Stuttgart (DE)

(72) Inventors: Florian BURGER, Wendlingen (DE); Markus WIEDEMANN, Soergenloch (DE); Robert KORNHAAS, Spraitbach (DE)

(21) Appl. No.: 18/832,779

(22) PCT Filed: Jan. 31, 2023
(86) PCT No.: PCT/EP2023/052266

§ 371 Date: Jul. 24, 2024

(30) Foreign Application Priority Data
Feb. 28, 2022 (DE) 10 2022 202 015.4

(51) Int. Cl. H05K 7/20; H05K 5/00

(52) U.S. Cl. CPC H05K 7/20854; H05K 5/0065; H05K 7/20863; H05K 7/20881

(57) ABSTRACT

A device with exchangeable electronics assemblies of a motor vehicle. The device includes a housing to at least partially enclose the electronics assemblies exchangeable in an insertion direction, an insertion mechanism for receiving the exchangeable electronics assemblies, a front side which is at least partially detachably connected to the housing and via which access to the exchangeable electronics assemblies arranged inside the housing is possible. A rear housing cover and a circuit board which is aligned transversely to an insertion direction of the electronics assemblies and serves to contact the exchangeable electronics assemblies are provided. The electronics assemblies respectively include an electronics component to be cooled and at least one heat-conducting element which is in thermal contact with the electronics component, and for thermally connecting a cooler, the heat-conducting element has a contact surface oriented transversely to the insertion direction, and the cooler arranged in front of the circuit board, when viewed in the insertion direction, for cooling a plurality of electronics assemblies.

### FIELD

The present invention relates to a device with exchangeable electronics assemblies of a motor vehicle.

### BACKGROUND INFORMATION

Systems and methods for passive cooling of components within electrical devices are described in European Patent Application No. EP 2961252 A1. An electrical unit comprises a rear plane structure with openings and a heat sink arranged in parallel with the rear plane structure and along the rear end of the control cabinet.

### SUMMARY

An object of the present invention is to provide an improved thermal connection, in particular in the insertion direction. This object may be achieved by features of the present invention.

The device according to an example embodiment of the present invention transfers heat between the exchangeable electronics assembly and the housing in the insertion direction, not laterally. This achieves a relatively low thermal resistance since the direction of the thermal contact matches the direction of the electrical contact toward the mechanical fastening. At the same time, both the electrical contact with the rear circuit board and the thermal contact with the cooler can also be realized by inserting the electronics assembly. Sufficient thermal contact is achieved, for example, through the corresponding surface pressure.

In an expedient development of the present invention, it is provided that the cooler is arranged between the circuit board and the exchangeable electronics assembly, in particular the housing thereof, or in front of the electronics assembly with respect to the insertion direction. Thanks to the relative proximity of the cooler to the heat-generating electronics component, the heat-conducting element can be designed to be relatively compact.

In an expedient development of the present invention, the heat-conducting element has at least one surface, oriented in parallel with the insertion direction, for dissipating the waste heat generated by the electronics component. Via the surface, which is connected directly or via a further component, in particular the flexible thermal conduction medium, and is substantially in parallel with the surface of the electronics component, a particularly good thermal connection can be achieved.

In an expedient development of the present invention, the electronics assembly comprises at least one, in particular frame-shaped, carrier for receiving at least one circuit board and/or at least part of a housing. The carrier may preferably also cooperate with the insertion mechanism or the receptacles in the housing. This results in a simple and stable structure of the electronics assembly.

In an expedient development of the present invention, at least one further heat-conducting element or thermal conduction medium, in particular made of flexible thermal conduction material, is arranged between the heat-conducting element and the cooler and/or the electronics component. This achieves good thermal connection, which can be further improved by applying a surface pressure.

In an expedient development of the present invention, it is provided that the heat-conducting element comprises at least one heat-conducting plate, in particular made of copper or aluminum, and/or at least one cavity, which is in particular rectangular or tubular, particularly preferably formed as a vapor chamber and/or as a heat pipe, and is filled with a heat-conducting medium. This allows a particularly good heat dissipation to be flexibly realized depending on the existing geometry.

In an expedient development of the present invention, the heat-conducting element is in contact with at least part of a housing of the electronics assembly. The waste heat of any further electronics components to the cooler can also be realized particularly simply via the housing, which in turn is connected to the heat-conducting element.

In an expedient development of the present invention, the cooler is configured to be flowed through by a cooling medium. Alternatively, the cooler may be configured for air cooling, in particular by providing cooling fins and at least one fan. Particularly preferably, the cooler may be integrated in the front side of the device. As a result, particularly powerful cooling can preferably be carried out for all electronics assemblies. The integration in the front side is characterized by a particularly simple structure and is in particular suitable for air cooling. By closing the front side, the further thermal conduction medium can also be pressed particularly simply.

In an expedient development of the present invention, the cooler has at least one opening through which a plug of the electronics assembly for contacting the circuit board at least partially projects. It is thus simple to establish contact between the electronics assemblies and the circuit board arranged at the rear.

In an expedient development of the present invention, a pressing means, in particular at least one screw or lever, is provided in order to reduce the relative distance between the heat-conducting element or contact surface, in particular in order to achieve pressing of the further heat-conducting element located between the heat-conducting element or contact surface and the cooler. The electronics assemblies can thereby be fixed in the device. In addition, the force required for finally plugging in the plugs and pressing the further heat-conducting element can be applied particularly simply.

Further expedient developments of the present invention arise from the disclosure herein.

### BRIEF DESCRIPTION OF THE DRAWINGS

FIG. 1 shows a total perspective exploded view of an exemplary embodiment of a device with a plurality of exchangeable electronics assemblies, according to the present invention.

FIG. 2 shows a side view of an exchangeable electronics assembly of the present invention.

FIG. 3 shows a rear perspective view of the exchangeable electronics assembly of the present invention.

FIG. 4 shows a side view of a plurality of exchangeable electronics assemblies, together with cooler, rear circuit boards and carrier plate in the assembled state, according to an example embodiment of the present invention.

FIG. 5 shows a side view of an alternative exemplary embodiment of an exchangeable electronics assembly of the present invention.

FIG. 6 shows a side view of a further alternative exemplary embodiment of an exchangeable electronics assembly of the present invention.

FIG. 7 shows a perspective view of the exemplary embodiment according to FIG. 6.

FIG. 8 shows a perspective view of a housing of the exemplary embodiment according to FIGS. 6 and 7.

FIG. 9 shows a frontal sectional view of a further alternative exemplary embodiment of the present invention.

FIG. 10 shows a sectional side view of the further alternative exemplary embodiment according to FIG. 9.

FIG. 11 shows a side view of a further alternative exemplary embodiment of the present invention.

FIG. 12 shows a side view of a plurality of exchangeable electronics assemblies according to FIG. 5, together with a cooler integrated in the maintenance flap, according to the present invention.

FIG. 13 shows a side view of a plurality of exchangeable electronics assemblies for air cooling, according to an example embodiment of the present invention.

### DETAILED DESCRIPTION OF EXAMPLE EMBODIMENTS

The present invention is shown schematically on the basis of a plurality of exemplary embodiments and is described extensively below with reference to the figures.

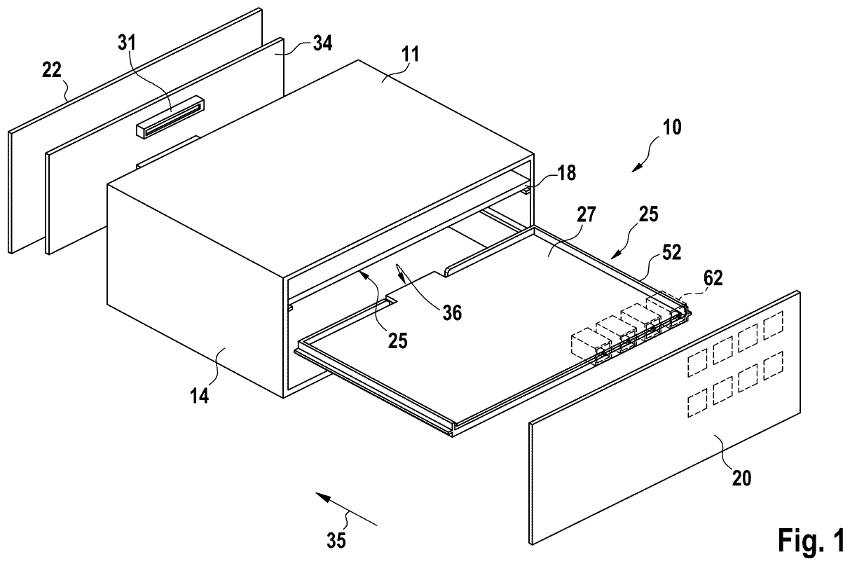

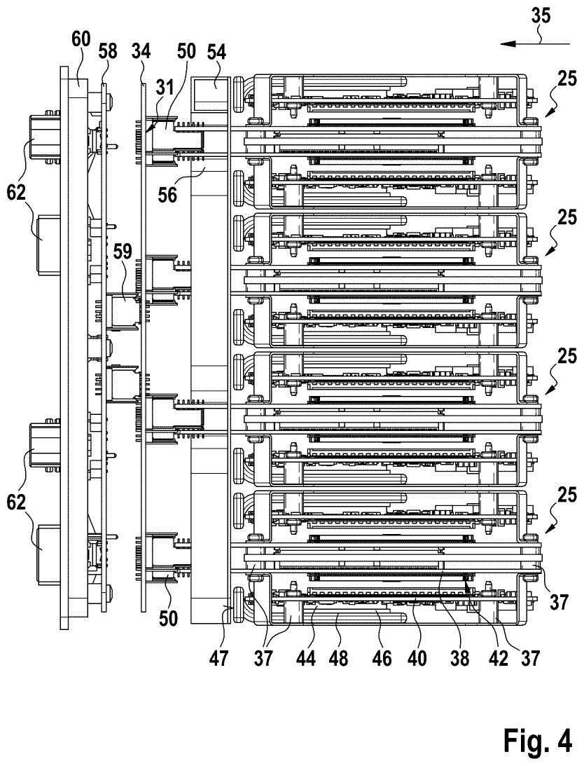

In FIG. 1, the device 10 comprises at least two electronics assemblies 25 and a housing 11 at least partially surrounding them. Depending on the application, however, further electronics assemblies 25 can also be arranged exchangeably in the housing 11. The housing 11 has two side surfaces 14. The housing 11 is closed at the rear via a rear housing cover 22, in particular by a mechanical fixation, such as a screw connection. At least one circuit board 34 is arranged in parallel with the rear housing cover 22 and perpendicularly to the exchangeable electronics assemblies 25 or an insertion direction 35 of the electronics assemblies 25. Plug connections 31, which establish electronic contact between the individual electronics assemblies 25 and the circuit board 34, are provided on the circuit board 34. By way of example, further electronics components (not shown explicitly), which, for example, control the communication processes, are provided on the circuit board 34. Plugs 62 for outward contacting can be placed via the circuit board 34. More precise details of the components arranged on the rear side of the device 10 can in particular be taken from FIG. 4.

Optionally, plugs 62 may be attached to the front side of the circuit board 38 and in that case project through corresponding openings (also indicated with dashes) in the front side 20.

The front side 20 provides access to the exchangeable electronics assemblies 25 arranged inside the device 10. The front side 20 is to be opened and closed via mechanical fixations. As an example of a possible insertion mechanism, a plurality of receptacles 18 are in each case provided on the inner side of the side surfaces 14 of the housing 11. These substantially rail-shaped receptacles 18 serve to reversibly receive, insert, and/or clamp the exchangeable electronics assemblies 25 in the insertion direction 35. The electronics assembly 25 may, for example, comprise one or more circuit boards 38, 40, or an electronics unit. The electronics units with associated electronics components 44 (shown later) in particular comprise high-performance computer cores, which take on particularly computationally intensive functions in the motor vehicle. These functions may, for example, be autonomous or partially autonomous driving functions, infotainment, communication interfaces between different bus systems (Ethernet, CAN, LIN, etc.) or gateway functionalities, certain security applications for granting authorization to also access the motor vehicle from the outside, for example, or further operations associated with, in particular high, computing power in the motor vehicle. The electronics components 44 are particularly preferably powerful processors, multi-core processors or highly integrated circuits (SoC, system-on-chip), which are characterized by high power losses.

The circuit board 38, 40 of the electronics assembly 25 is at least partially enclosed from at least one side by a housing 52 or a housing half 52. In the side regions, the housing half 52 ends in corresponding protrusions, which can be placed onto the receptacles 18 in the housing 11 or inserted into the receptacles 18. In this exemplary embodiment, the housing half 52 laterally encloses the circuit board 38, 40 almost entirely.

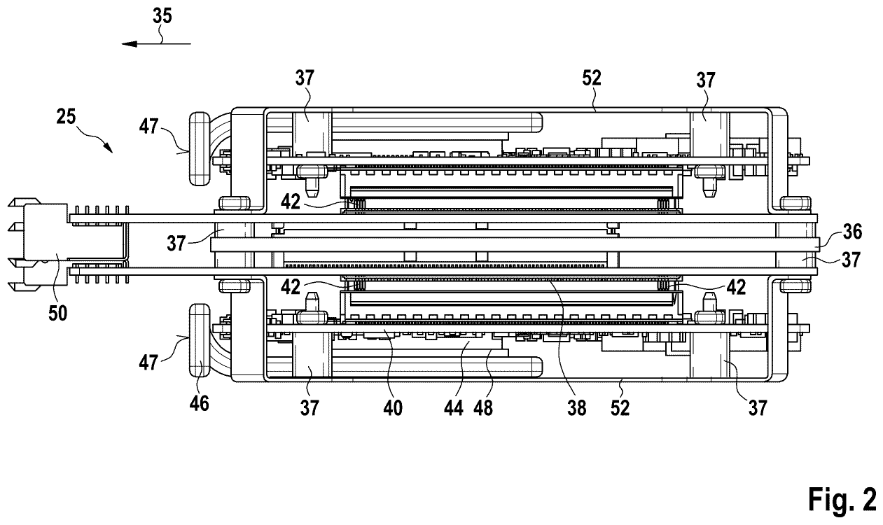

The exemplary embodiment according to FIG. 2 shows an exchangeable electronics assembly 25 by way of example. A circuit board 38 is fastened to a stable carrier 36. This takes place, by way of example, by means of fastening means 37, which can be designed as screw connections with spacer sleeves. The circuit board 38 could, for example, comprise the main board. In the exemplary embodiment, a further circuit board 40 is additionally arranged in parallel with the circuit board 38. However, depending on the exemplary embodiment, only a single circuit board 38 could also be provided. Electronics components 44 are likewise arranged on the further circuit board 40, for example as a so-called daughter board. Such electronics components 44, which are characterized by high heat generation, are arranged on the further circuit board 40 in the exemplary embodiment. For dissipating the waste heat of these electronics components 44, a thermally conductive connection 48 is used to thermally connect to a heat-conducting element 46. This thermal connection 48 is, for example, designed as a so-called gap pad, a flexible heat-conducting material. Electronics components 44 that cannot be placed onto the further circuit board 40 but are nevertheless to be thermally connected to a cooler 54 must be arranged in the region of the bent heat-conducting element 46 and must also be thermally contacted therewith. Alternatively, the electronics components 44 can also be connected via the housing 52, which is, for example, formed from a heat-conducting material, such as aluminum, to the heat-conducting element 46 and/or via further heat-conducting elements, such as heat pipes (tubular heat-conducting arrangements, filled with a heat-conducting medium where appropriate).

On the one side, the heat-conducting element 46 is oriented substantially in parallel with the surface of the further circuit board 40. At the other end, it projects beyond the end of the further circuit board 40. In this region, the heat-conducting element 46 has a contact surface 47 to the cooler 54. The contact surface 47 is oriented substantially transversely to the circuit board 38, 40 or transversely to the insertion direction 35 of the electronics assembly 25. The contact surface 47 is preferably designed as a flat plane. The normal vector of this plane is parallel to the insertion direction 35. For improving the heat transfer, the contact surface 47 can extend at least almost over the entire width of the further circuit board 40. The heat-conducting element 46 could, for example, be designed as a so-called vapor chamber or heat pipe 45, a hollow body or tube filled with a heat-conducting medium. Alternatively, the heat-conducting element 46 consists only of a particularly heat-conducting material, such as copper or the like, and could, for example, be designed as a solid part without a cavity in the shape of a plate. The heat-conducting element 46 could be designed as an insert.

Furthermore, at least one housing half 52 is provided, which at least partially encloses the circuit boards 38, 40 and the heat-conducting element 46. In particular, four arms of the housing half 52 project outward beyond the outer sides of the further circuit board 40. The arms of the housing half 52 end in the shape of an L and can thus rest on the circuit board 38 at the corners thereof and be connected, for example screwed, via the fastening means 37 to the carrier 37. For exchanging the circuit boards 38, 40 later, the fastening means 37 can be easily detached again. Contacting 42 is provided between the two circuit boards 38, 40 in order to electrically connect the further circuit board 40 to the circuit board 38. At least one plug 50 is arranged on the face side of the circuit board 38. When the electronics assembly 25 is inserted into the housing 11, the electronics assembly 25 is electrically connected via this plug 50 and the rear circuit board 34.

The exemplary embodiment according to FIG. 2 is symmetrical (with the carrier 36 as the axis of symmetry). Four circuit boards 38, 40 may thus even be accommodated in the exchangeable electronics assembly 25. In this case, two housing halves 52 are provided, each connecting two circuit boards 38, 40 to the carrier 36 to form one structural unit. A further plug 50 serves to electrically connect the second half to the further circuit boards 38, 40.

The carrier 36 preferably protrudes somewhat laterally in the insertion direction 35 in relation to the parallel outer sides of the circuit boards 38 so that the carrier 36 can be inserted into the receptacles 18 or the insertion mechanism on the housing 11.

Common to this and all further exemplary embodiments is that the plug 50 protrudes further in the insertion direction 35 than the contact surface 47.

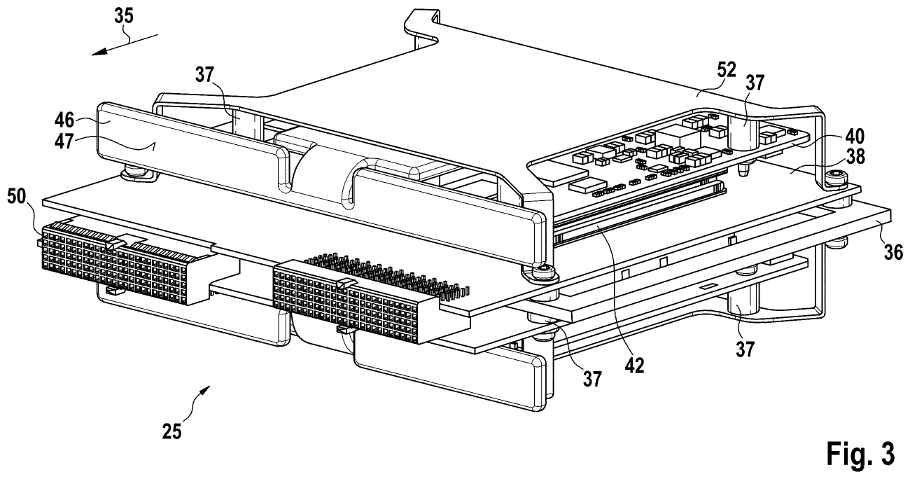

FIG. 3 shows a perspective view of the exchangeable electronics assembly 25. It can be seen that the contact surface 47 of the heat-conducting element 46 extends substantially over the entire width of the circuit board 38. The contact surface 47 is substantially rectangular in shape. In an, in particular central, region of the heat-conducting element 46, the contact surface 47 oriented transversely to the insertion direction 35 is connected to a portion of the heat-conducting element 46 that is aligned in parallel with the circuit board 38, 40. This portion of the heat-conducting element 46 that is aligned in parallel with the circuit board 38, 40 is thermally conductively connected to the electronics component(s) via a thermal connection 48, for example. A portion of the circuit board 38 projects beyond the contact surface 47 in the insertion direction 35 and is provided with the plugs 50 at the end.

In the exemplary embodiment according to FIG. 4, a vertical cooler 54 is arranged between a plurality of, in particular at least two, exchangeable electronics units 25 and at least one rear circuit board 34 oriented transversely to the circuit boards 38, 40. When the electronics assemblies 25 are inserted, their plug 50 dips through an opening 56 in the cooler 54 into the region of the rear circuit board 34 and contacts a corresponding mating plug there. At the same time, a further heat-conducting element 49, in particular a so-called gap pad (a flexible heat-conducting material that thermally bridges a gap between the heat-conducting element 46 and the cooler 54), is pressed between the heat-conducting element 46 and the cooler 54. A loosely guided screw is, for example, used to fix the exchangeable electronics assemblies 25. This screw meets a thread in the cooler 54 and is tightened from the front side 20 (maintenance flap) after the insertion of the electronics assemblies 25. The force 49 required for finally plugging in the plugs 50 and pressing the further heat-conducting element can be applied by means of the screw. Alternatively, two levers on the sides of the electronics assemblies 25 could apply this force.

The cooler 54 is oriented transversely to the insertion direction 35 of the electronics assemblies 25. The openings 56 in the cooler 54 are sized in the insertion direction 35 such that the respective plugs 50 can be pushed through them. Cooling circuits through which a heat medium, such as water, flows could, for example, be provided in the cooler 54. Corresponding connections to the cooler 54 for a coolant circuit are to be provided. Redundant cooling could be realized by the cooler 54 including at least two independent water circuits to which at least two independent cooling circuits are connected. Alternatively, the cooler 54 could also be provided with cooling fins in order to deliver the heat to an air flow. Preferably, the cooler 54 is arranged in front of the rear circuit board 34. However, this could also be in the region of the front side of the device 10. The cooler 54 cools at least two, preferably a plurality of, exchangeable electronics assemblies 25. Due to the arrangement of the cooler 54 transverse to the insertion direction 35 and also the corresponding alignment of the contact surface 47 of the heat-conducting element 46 transverse to the insertion direction 35, high thermal contacting can be achieved, for example by surface pressure, when the electronics assemblies 25 are inserted.

In the exemplary embodiment according to FIG. 4, the housing 11 is closed by a rear housing cover 22, which is designed as a carrier 60 or carrier plate for plugs 62. The device 10 or the exchangeable electronics assemblies 25 located therein are externally contacted via these plugs 62 in that the plugs 62 are electrically conductively connected to a further rear circuit board 58 (so-called backplane) oriented transversely to the insertion direction 35. Via further connections, this further rear circuit board 58 is connected to the rear side of the rear circuit board 34 arranged in parallel therewith, while, on the front side thereon, the plugs 50 of the electronics assemblies 25 are received in mating plugs oriented toward the exchangeable electronics assemblies 25. Alternatively, however, only a single rear circuit board 34 could be provided as indicated in FIG. 1.

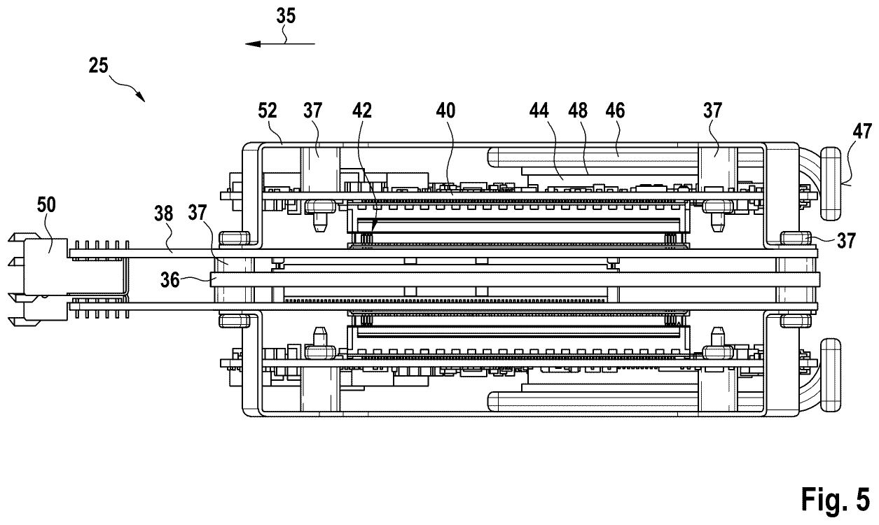

Alternatively, the cooling function may also be integrated into the front side (maintenance flap) to be opened. This is shown by way of example in FIG. 5, 11-13. In this case, the heat-conducting element 46 is mounted, rotated by 180°, onto the electronics assembly 25. The contact surface 47 is thus arranged on the side of the circuit board 38, 40 that is opposite the plug 50. The contact surface 47 now projects forward beyond the circuit boards 38, 40 in order to thus come into thermal contact with the front side 20 designed as the cooler 54. The thermal contact is established by closing the front side 20 and by the accompanying pressing of the further heat-conducting element 49, which is arranged between the outer side of the contact surface 47 and the inner side of the cooler 54. Otherwise, the structure remains the same as described in connection with FIGS. 2 and 3. In particular, the contact surface 47 is again oriented transversely to the insertion direction 35. The surface of the cooler 54 for thermal connection to the heat-conducting element 46 is accordingly likewise formed transversely to the insertion direction 35 or in parallel with the rear circuit board 34 and arranged in front of the rear circuit board 34 but also in front of the exchangeable electronics assemblies 25.

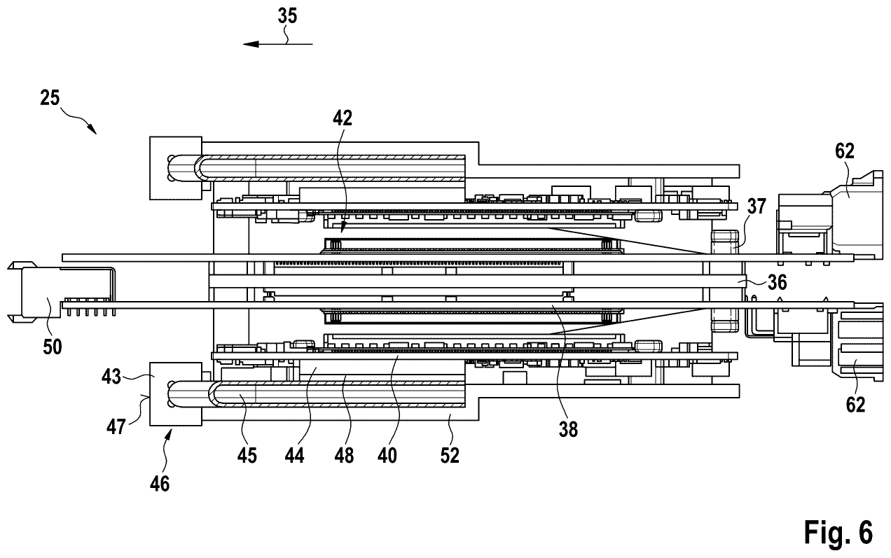

FIG. 6 shows a further exemplary embodiment of the electronics assembly 25 in section. On the one hand, the exemplary embodiment differs from the preceding ones in that at least one external plug 62 is arranged on the front side (with respect to the insertion direction 35) of the electronics assembly 25. The plug 62 is arranged on the circuit board 38 in the exemplary embodiment. The contacting direction of the plug 62 is parallel to the insertion direction 35. Depending on the application, even further plugs 62 may be arranged on the circuit board 38. The plugs 62 project beyond the face-side beginning of the circuit board 38. Accordingly, corresponding recesses through which these plugs 62 project are provided in the front side 20 to be opened. Nonetheless, for contacting the transverse rear circuit board 34, at least one plug 50 is again provided at the end of the electronics assembly 25. As in the exemplary embodiments above, the plug 50 is arranged at the end of the somewhat protruding circuit board 38.

The exemplary embodiment according to FIG. 6 again comprises the carrier 36, on which the circuit board 38 and a further circuit board 40 are held via the fastening means 37 and housing 52. The electronics component 44 to be cooled is arranged on the further circuit board 40. Contacting 42 is provided between the two circuit boards 38, 40. Again, the exemplary embodiment is symmetrical, with the carrier 36 as the axis of symmetry. Two circuit boards 38, 40 are again arranged on the bottom side. Located on this further circuit board 40 is also a further electronics component 44 to be cooled, which is cooled via a further heat-conducting element 46 via contact surfaces 47, oriented transversely to the insertion direction 35, via a cooler 54 not shown. Further contacting could likewise be provided between the two circuit boards 38, each carrying the plugs 50, 62.

In the exemplary embodiment according to FIG. 6, the heat-conducting element 46 is formed in at least two parts. It comprises at least one or more heat pipes 45 (tubular heat-conducting arrangement filled with a heat-conducting medium particularly suitable for this purpose). The heat pipe 45 is thermally connected, for example via the thermal connection 48, to the electronics component 44, whose heat is to be dissipated. In a portion adjacent to the electronics component 44 to be cooled, the heat pipe 45 is arranged in the electronics assembly 25, in particular in parallel with the insertion direction 35. The heat pipe 45 is in thermal contact with a further heat-conducting element, a profile or end piece 43, which forms the contact surface 47 formed perpendicularly to the insertion direction 35. This end piece 43 is, for example, a profile part made of a heat-conducting material, for example an L-profile or U-profile 43 made of copper or the like. A corresponding recess of the further heat-conducting element or end piece or profile 43 is used to thermally connect the heat pipe 45. For this purpose, the heat pipe 45 is bent by 90° and thus extends transversely to the insertion direction 35. The further heat-conducting element or profile 43 receives the 90°-bent portion of the heat pipe 45 or at least partially encloses this portion of the heat pipe 45 in order to achieve good thermal connection of the heat pipe 45 to the contact surface 47 of the further heat-conducting element or profile 43. The further heat-conducting element 43 or end piece 43 and the heat pipe 45 together form the heat-conducting element 46.

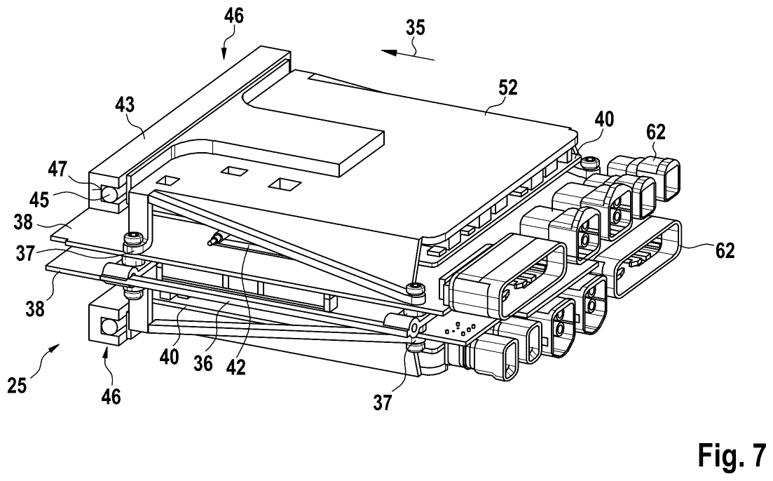

FIG. 7 shows a perspective plan view of the electronics assembly 25 according to FIG. 6. It can be seen that the further heat-conducting element 43 or end piece with the contact surface 47 extends almost over the entire width of the circuit board 38 or the further circuit board 40 and is connected to the housing 52 at the face side thereof. For receiving the heat pipe 45, the housing 52 is curved outward in the central region oriented toward the end piece 43. This view additionally shows that the end piece 43 is designed as a U-profile, which on three sides encloses the portion of the heat pipe 45 that is oriented transversely to the insertion direction 35, in order to ensure good heat transfer between the heat pipe 45 and the end piece 43 with the contact surface 47 oriented transversely to the insertion direction 35.

The carrier 36 protrudes laterally in parallel with the insertion direction 35 with respect to the side surface of the circuit board 38 that projects farthest outward or the superjacent housing 52. In this region, the carrier 36, in cooperation with the receptacle 18 on the housing 11, serves as the insertion mechanism for the exchangeable electronics assembly 25. The housing halves 52 protect at least the circuit boards 38, 40 from above and below, while the face sides of the electronics assembly 25 are protected from environmental influences via the front side 20 and the rear housing cover 22.

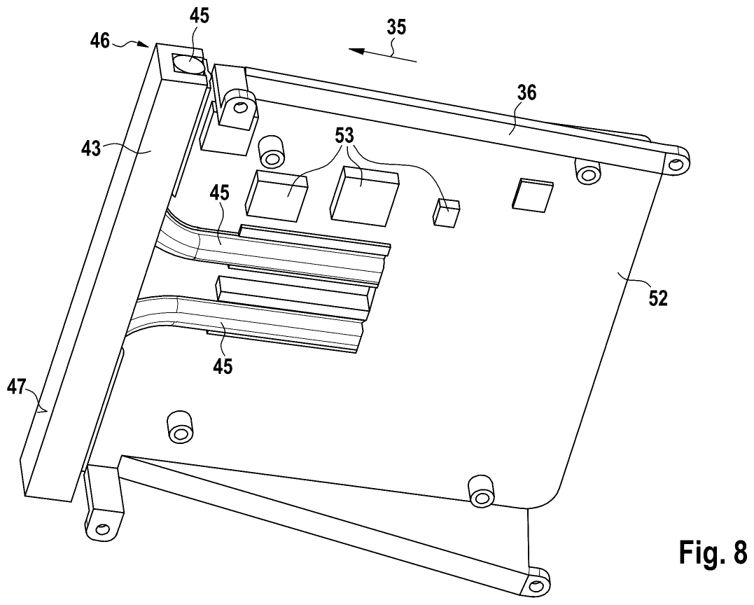

FIG. 8 shows a perspective view from the inside of a housing half 52 as used for the exemplary embodiments according to FIGS. 6 and 7. The inner side of the housing 52 has a receptacle for the two heat pipes 45 in the central region on the side oriented toward the end piece 43. Brackets (not denoted in detail) into which the heat pipe 45 can in each case be clamped or inserted may be provided for this purpose. In addition, the inner side of the housing 52 comprises, by way of example, at least one contact surface 53 protruding inward. This contact surface 53 can serve to cool further electronics components 44, which are thermally conductively connected to the contact surface 53 via a further thermal connection 48 where appropriate. The housing half 52 again consists of heat-conducting material and is connected to the heat-conducting element 46. In the exemplary embodiment according to FIG. 8, the cooling can take place via the portion of the heat pipe 45 that is inserted into the housing 52 and/or via the portion of the heat pipe 45 that is oriented transversely to the insertion direction 35 and thermally connected to the face side of the housing 52 and/or via the end piece 43, which is likewise thermally coupled to the face side of the housing 52.

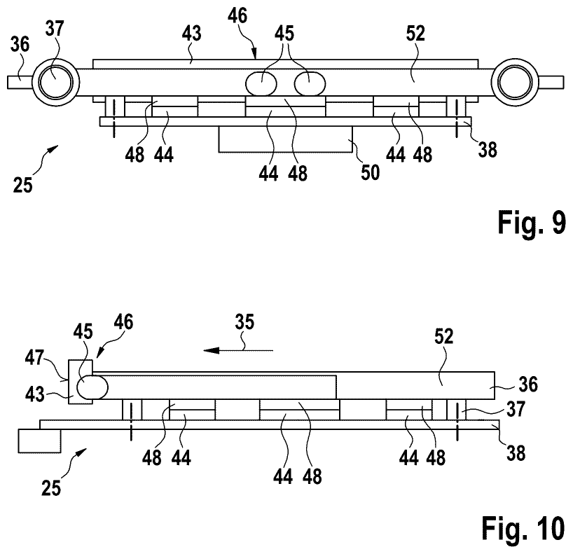

FIG. 9 shows a section of the front view of a further exemplary embodiment, which is characterized by only a single circuit board 38. The principle of the heat transfer and of the plug-in direction of the plug 50 parallel to the insertion direction 35 remains in place. A plurality of electronics components 44 to be cooled are arranged on the circuit board 38. For dissipating heat, one of the electronics components 44 is, by way of example, thermally conductively connected via the thermal connection 48 to at least one heat-conducting element 46 comprising one heat pipe 45 or two heat pipes 45. The heat pipes 45 are received in the housing 52 and initially extend in parallel (as shown in FIG. 10) with the insertion direction 35. After a 90° bend, the heat pipes 45 extend transversely to the insertion direction 35 and are at least partially enclosed by the end piece 43 in a thermally conductive manner. The end piece 43 again has a contact surface 47, oriented transversely to the insertion direction 35, to the cooler 54 not shown in this image. Heat pipes 45 and end piece 43 again form the heat-conducting element 46.

Further electronics components 44 can be thermally conductively connected via thermal connections 48 either likewise to the heat pipe 45 or directly to the housing 52. In this case, heat dissipation can take place via the housing 52 to the heat-conducting element 46.

The plug 50 is also arranged on the circuit board 38. It is characterized by a plug-in direction parallel to the insertion direction 35. The plug 50 is located at the end of the circuit board 38 and, for contacting the rear circuit board 34, projects slightly beyond the circuit board 38, as can be seen in FIG. 10. The plug 43 can be passed through an opening 56 in the cooler 54 so that the contact surface 47 is thermally connected to the cooler 54, for example via the thermal connection or the thermal conduction medium 49.

In particular, if only a single circuit board 38 is used per electronics assembly 25, the functional division into heat conduction (which is, for example, located in the housing 52 or lid in the arrangements with a plurality of circuit boards 38, 40) and guidance and force introduction (which is located in the carrier 36 in the arrangements with a plurality of circuit boards 38, 40) are combined in one component. This one component according to FIGS. 9 and 10 is the housing 52, wherein the carrier 36 is now part of this housing 52. The housing 52 thus also comprises a guide for mechanical fixation 37 and serves equally to hold the heat-conducting element 46, in particular the heat pipe(s) 45 used in this exemplary embodiment. Furthermore, the housing 52 is mechanically connected to the circuit board 38.

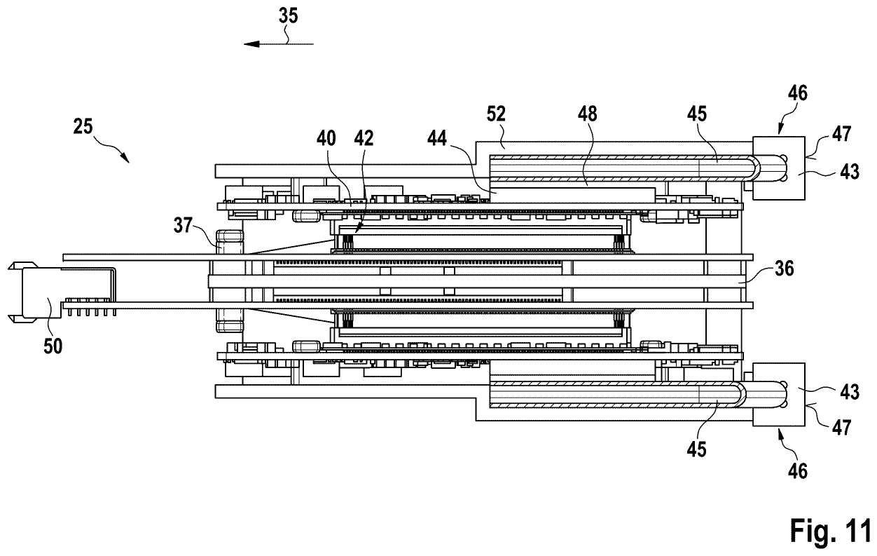

The exemplary embodiment according to FIG. 11 is again characterized by cooling via the front side 20, similarly to the exemplary embodiment according to FIG. 5. It differs therefrom only in that the heat-conducting element 46 consists of heat pipe 45 and end piece 43. The end piece 43 again has the contact surface 47, oriented forward transversely to the insertion direction 35, to the cooler 54. The end piece 43 is connected to the front side of the lid 52, also thermally for the heat dissipation of such electronics components 44, which dissipate their heat via the lid 52. For cooling, the heat pipe 45 can again be connected to the electronics component 44 via a thermal connection 48.

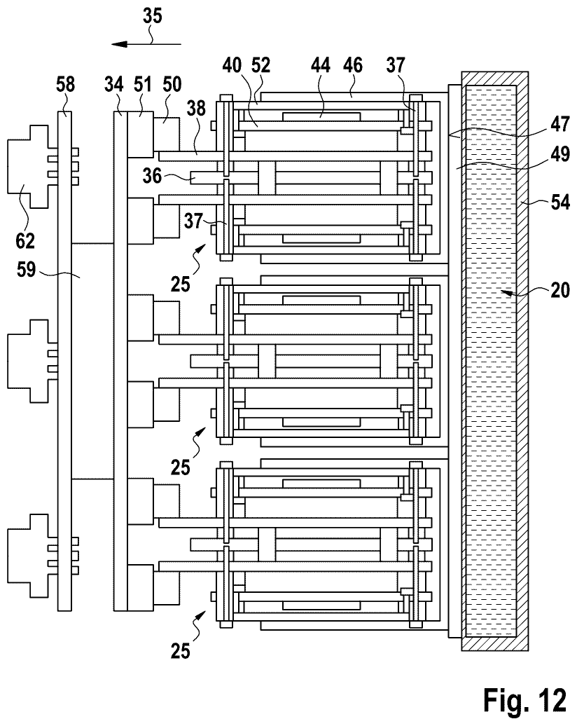

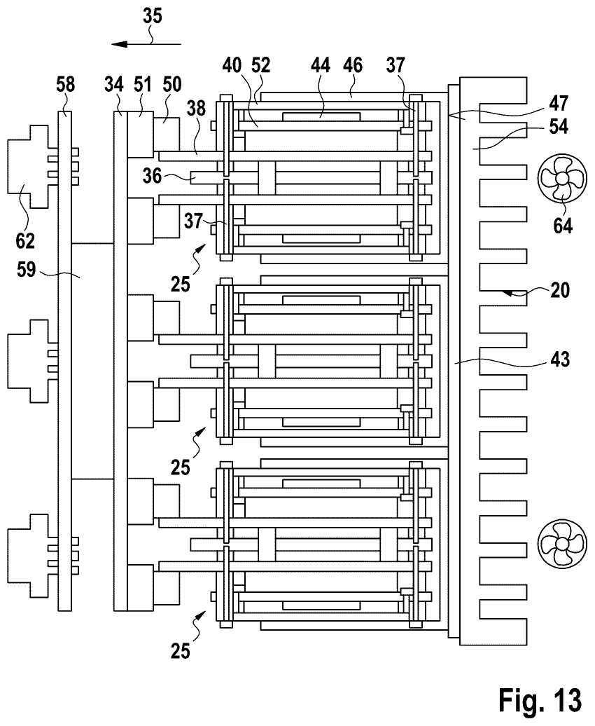

In the exemplary embodiment according to FIG. 12, the front side 20 designed as the cooler 54 could have the function of a water cooler. In the exemplary embodiment according to FIG. 13, the front side 20 designed as the cooler 54 could, for example, be provided with cooling fins in order to deliver the heat to an air flow, for example generated by fans 64.

The device 10 is used in particular for exchangeable electronics components in the motor vehicle sector. In the exchangeable electronics assemblies 25 with high cooling requirements, computationally intensive functions in the motor vehicle sector can in particular be realized, such as partially autonomous or autonomous driving, communication modules, gateway functionalities, infotainment, safety applications, etc. Such functions may respectively be realized in an exchangeable electronics assembly 25. The exchangeability also allows later retrofitting of current hardware in that electronics assemblies 25 can be easily exchanged.

1-15. (canceled)

16. A device with exchangeable electronics assemblies of a motor vehicle, the device comprising:
at least one housing to at least partially enclose the electronics assemblies which are exchangeable in an insertion direction;
at least one insertion mechanism configured to receive the exchangeable electronics assemblies;
at least one front side which is at least partially detachably connected to the housing and via which access to the exchangeable electronics assemblies arranged inside the housing is possible;
a rear housing cover;
at least one circuit board which is aligned transversely to the insertion direction of the exchangeable electronics assemblies and serves to contact the exchangeable electronics assemblies;
wherein the exchangeable electronics assemblies respectively include at least one electronics component to be cooled and at least one heat-conducting element which is in thermal contact with the electronics component; and
wherein, for thermally connecting a cooler, the heat-conducting element has a contact surface oriented transversely to the insertion direction; and
wherein the device further comprises the cooler arranged in front of the circuit board, when viewed in the insertion direction, for cooling a plurality of the exchangeable electronics assemblies.

17. The device according to claim 16, wherein the cooler is arranged between the circuit board and housings of the exchangeable electronics assemblies, or in front of the exchangeable electronics assemblies with respect to the insertion direction.

18. The device according to claim 16, wherein the heat-conducting element of each exchangeable electronics assembly has at least one surface oriented in parallel with the insertion direction, for dissipating waste heat generated by the electronics component of the exchangeable electronics assembly.

19. The device according to claim 16, wherein each exchangeable electronics assembly includes: (i) at least a frame-shaped carrier: (i) for receiving at least one circuit board and/or at least part of a housing of the exchangeable electronics assembly and/or (ii) for mechanical contact with receptacles arranged in the housing of the device.

20. The device according to claim 16, wherein at least one further heat-conducting element including a flexible thermal conduction material, is provided between the heat-conducting elements and: the cooler and/or the electronics components.

21. The device according to claim 16, wherein each heat-conducting element includes: (i) at least one heat-conducting plate made of copper or aluminum, and/or (ii) at least one cavity which is rectangular or tubular formed as a vapor chamber and/or for as a heat pipe, and is filled with a heat-conducting medium.

22. The device according to claim 20, wherein each heat-conducting element includes at least one end piece: (i) which is in thermal contact with a tubular heat-conducting element, and/or (ii) which has a profile for receiving a further heat-conducting element.

23. The device according to claim 16, wherein the heat-conducting element of each exchangeable electronics assembly is in contact with at least part of a housing of the exchangeable electronics assembly.

24. The device according to claim 16, wherein: (i) the cooler is configured to be flowed through by a cooling medium, and/or (ii) the cooler is configured for air cooling by providing cooling fins and/or at least one fan, and/or (iii) the cooler is integrated in the front side.

25. The device according to claim 16, wherein the cooler has at least one opening through which a plug of the exchangeable electronics assemblies at least partially projects for contacting the circuit board.

26. The device according to claim 20, wherein a pressing device including at least one screw or lever, is provided in order to reduce a relative distance between: (i) the heat-conducting elements or contact surfaces, and (ii) the cooler, to achieve pressing of the further heat-conducting element located between: (i) the heat-conducting elements or contact surfaces, and (ii) the cooler.

27. The device according to claim 16, wherein each exchangeable electronics assembly includes at least one circuit board with the at least one electronics component, and a housing at least partially surrounding the circuit board and the heat-conducting element, which is in thermal contact with the electronics component.

28. The device according to claim 27, wherein: (i) the housing of each exchangeable electronics assembly includes at least one arm which projects beyond a further circuit board, and/or (ii) the housing of each exchangeable electronics assembly can be connected to the circuit board of the exchangeable electronics assembly, and/or (iii) the housing of each exchangeable electronics assembly is configured for mechanically holding the further circuit board and/or is configured for holding the heat-conducting element and/or is configured for fastening to a carrier.

29. The device according to claim 16, wherein: (i) each exchangeable electronics assembly includes at least one plug, and/or (ii) the circuit board aligned transversely to the exchangeable electronics assemblies includes at least one plug connection for receiving a plug of the exchangeable electronics assemblies.

30. The device according to claim 16, wherein each exchangeable electronics assembly includes at least a circuit board and a further circuit board.
